(19) United States
(12) Patent Application Publication
(10) Pub. No.: US 2024/0347666 A1
(43) Pub. Date: Oct. 17, 2024

(54) OPTOELECTRONIC DEVICE

(71) Applicant: LITE-ON TECHNOLOGY CORPORATION, TAIPEI CITY (TW)

(72) Inventors: CHEN-HSIU LIN, NEW TAIPEI CITY (TW); Kai-Chieh Liang, New Taipei City (TW)

(21) Appl. No.: 18/634,247

(22) Filed: Apr. 12, 2024

Related U.S. Application Data
(60) Provisional application No. 63/459,378, filed on Apr. 14, 2023.

(30) Foreign Application Priority Data
Mar. 1, 2024 (CN) 202420400926.9

(51) Int. Cl. H01L 31/173; H01L 31/02; H01L 31/0203; H01L 31/0216

(52) U.S. Cl. CPC H01L 31/173; H01L 31/02005; H01L 31/0203; H01L 31/02164

(57) ABSTRACT

An optoelectronic device includes a substrate, a sensing element, a light emitting element, a first dam, and a second dam. The sensing element and the light emitting element are disposed on the substrate. The first dam is disposed on the substrate and covers a side of the sensing element. The second dam is disposed on the first dam. The first dam and the second dam are located between the sensing element and the light emitting element.

### CROSS-REFERENCE TO RELATED PATENT APPLICATION

This application claims the benefit of priority to China Patent Application No. 202420400926.9, filed on Mar. 1, 2024, in the People's Republic of China. The entire content of the above identified application is incorporated herein by reference.

This application claims the benefit of priority to the U.S. Provisional Patent Application Ser. No. 63/459,378, filed on Apr. 14, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optoelectronic device, and more particularly to a miniaturized optoelectronic device while improving the signal-to-noise ratio.

### BACKGROUND OF THE DISCLOSURE

Optical physiological sensors sense the physiological characteristics of the human body by comparing and detecting signal differences. Generally, the optical physiological sensors only sense light in a specific wavelength range. For preventing unnecessary light, i.e., so-called stray light, from entering the inside of the sensor and making the sensing results more accurate, a filter is used to filter the light that is not within the wavelength sensing range, so as to reduce energy loss caused by the light passing through the filter.

However, in existing optical physiological sensors, a plastic housing can be utilized to cover a sensing element and a light emitting element, and a filter can be used to attach to the plastic housing to cover an opening of the plastic housing to achieve the light filtering effect. This type of sensor device has a large size. In addition, an amount of glue required to fix the plastic housing to a substrate is difficult to control. When the amount of glue is too much, the glue can easily overflow and cause the plastic housing to shift.

### SUMMARY OF THE DISCLOSURE

In response to the above-referenced technical inadequacies, the present disclosure provides a miniaturized optoelectronic device while improving the signal-to-noise ratio.

In order to solve the above-mentioned problems, one of the technical aspects adopted by the present disclosure is to provide an optoelectronic device, which includes a substrate, a sensing element, a light emitting element, a first dam, and a second dam. The sensing element and the light emitting element are disposed on the substrate. The first dam is disposed on the substrate and covers a side of the sensing element. The second dam is disposed on the first dam. The first dam and the second dam are located between the sensing element and the light emitting element.

Therefore, in the optoelectronic device provided by the present disclosure, through structural design of the first dam covering a side of the sensing element, and the second dam being disposed on the first dam, the noise interference can be reduced, and the light receiving performance of the sensing element can be improved. Moreover, in the optoelectronic device provided by the present disclosure, the height of the overall structure can be reduced, so as to meet miniaturization trends in development.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an optoelectronic device according to a first embodiment of the present disclosure;

FIG. 2 is a partial schematic exploded view of the optoelectronic device according to the first embodiment of the present disclosure;

FIG. 3 is a schematic cross-sectional view of an implementation of the optoelectronic device according to the first embodiment of the present disclosure;

FIG. 4 is a schematic enlarged view of part IV of FIG. 3;

FIG. 5 is a schematic cross-sectional view of another implementation of the optoelectronic device according to the first embodiment of the present disclosure;

FIG. 6 is a schematic exploded view of a substrate of the optoelectronic device according to the present disclosure;

FIG. 7 is a schematic perspective view of an optoelectronic device according to a second embodiment of the present disclosure;

FIG. 8 is a partial schematic exploded view of the optoelectronic device according to the second embodiment of the present disclosure; and

FIG. 9 is a schematic cross-sectional view of the optoelectronic device according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

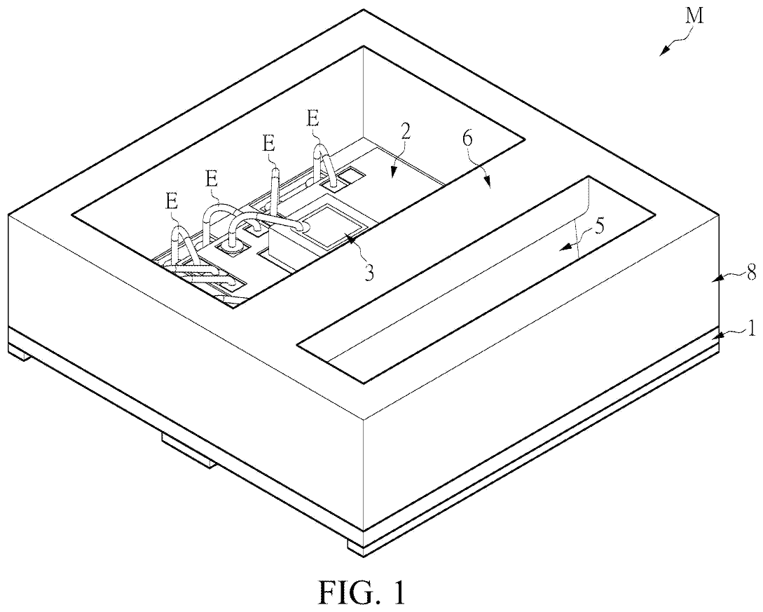

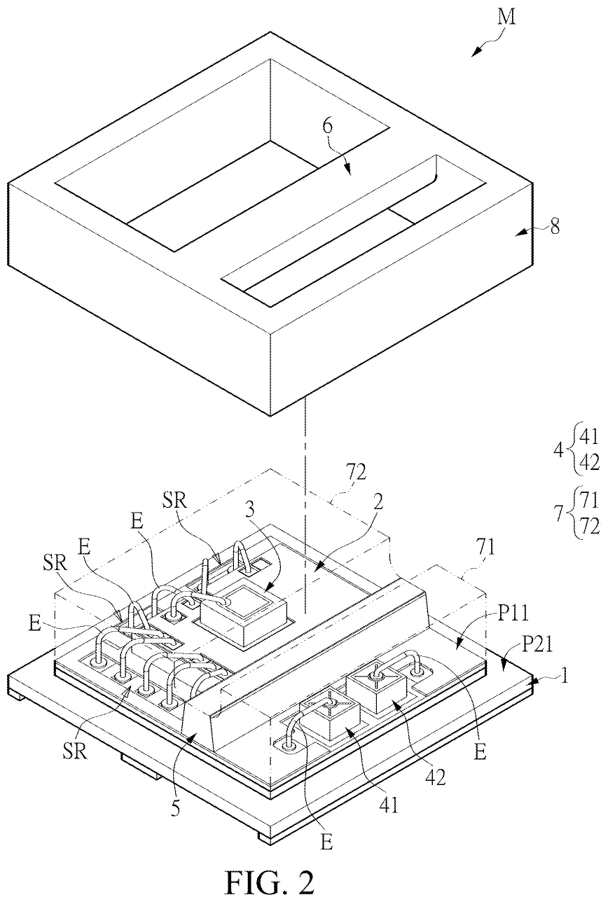

Referring to FIG. 1 and FIG. 2, a first embodiment of the present disclosure provides an optoelectronic device M, which includes a substrate 1, a sensing element, a light emitting element 4, a first dam 5, and a second dam 6. The substrate 1 can be a circuit board. The sensing element and the light emitting element 4 are disposed on the substrate 1, and the first dam and the second dam is formed as a light blocking structure configured to block light, especially emitted from the light emitting element 4.

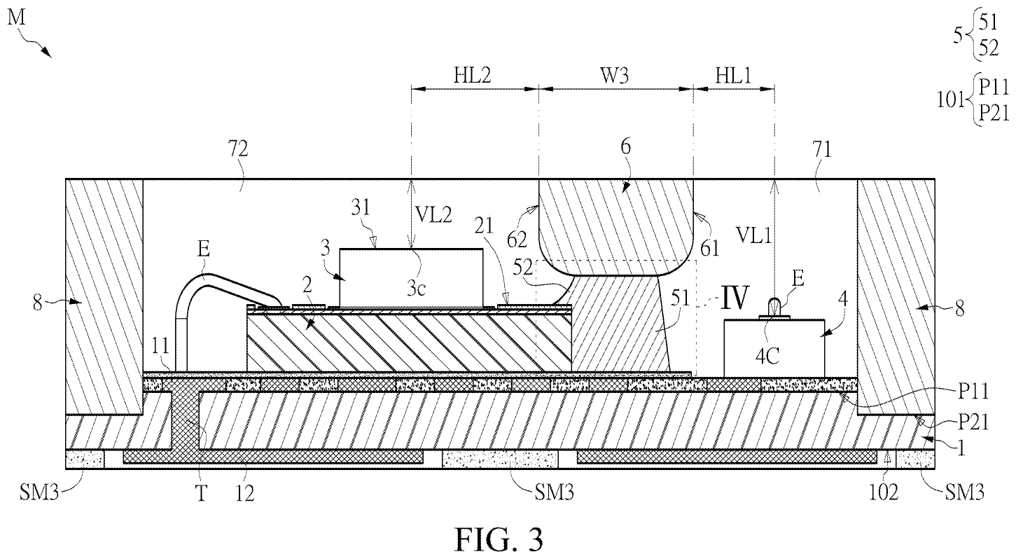

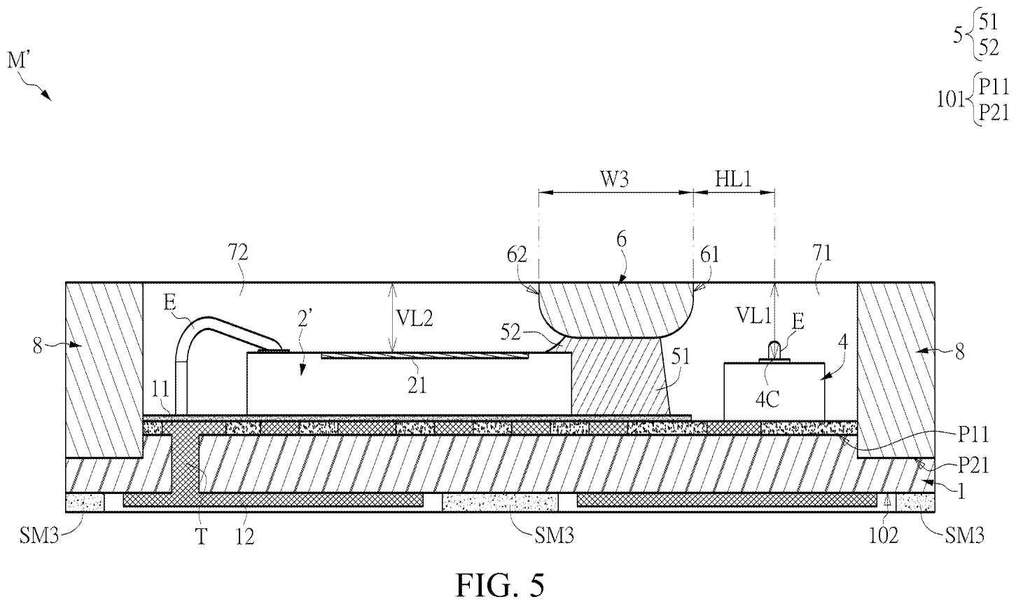

For example, the optoelectronic device M provided by the present disclosure is a photoelectric sensor, which is used to sense the physiological characteristics of a human body. The light emitting element 4 can be a combination of one or more light emitting diodes (LEDs) and laser diodes, which can emit light with different wavelength such as infrared light, ultraviolet light or visible light, for detection by the sensing element. Referring to FIG. 3 and FIG. 5, the sensing element can be a sensing unit 3 disposed on a carrier 2 (as shown in FIG. 3) or a carrier 2′ having a light detection area 20 on the surface thereof (as shown in FIG. 5).

Referring to FIG. 3, the carrier 2 is electrically connected to the sensing unit 3 and the substrate 1 (e.g., the circuit board) through internal circuits or internal structures thereof, so as to achieve the function of transmitting signals. Referring to FIG. 5, the sensing element can be a carrier 2′ having one or more light detection area 20 on the surface thereof, which may also include a filter for ambient light sensing (ALS). On the other hand, when the sensing element includes the carrier 2 or the carrier 2′, the carrier 2 or the carrier 2′ can be used for carrying the sensing unit, and the carrier 2 or the carrier 2′ can be a processor, a memory, an application specific integrated circuit (ASIC) or an analog front end (AFE) IC. In addition, it should be noted that the size of the optoelectronic device M′ shown in FIG. 5 can be further reduced.

The sensing unit 3 can be a photodetector, a phototransistor, a photodiode or a photo IC. The light emitting element 4 can emit the light to a surface of an external object such as a surface of human skin, and be reflected back to be received by the sensing element and converted into an electrical signal to detect changes in the state of the object such as the physiological characteristics of the human body.

The light emitting element 4 includes two light emitting units 41 and 42, which are used to emit near-infrared rays with a wavelength between 700nm and 1500 nm, but the present disclosure is not limited thereto.

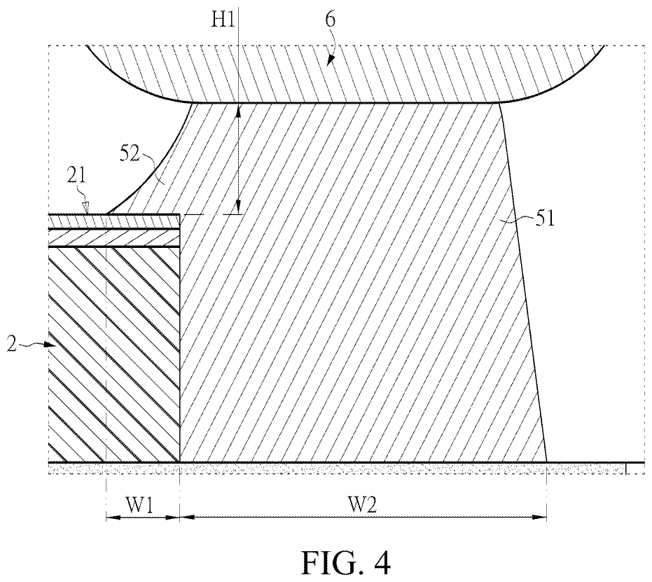

Referring to FIG. 3 and FIG. 4, the first dam 5 is disposed on the substrate 1, and the second dam 6 is disposed on the first dam 5. Specifically, a bottom of the second dam 6 contacts and covers a top of the first dam 5. A maximum width of the second dam 6 in a horizontal direction is greater than a maximum width of the first dam 5 in the horizontal direction. The first dam 5 and the second dam 6 are located between the light emitting element 4 and the sensing element. Therefore, the first dam 5 and the second dam 6 jointly form a barrier wall to partition the light emitting element 4 and the sensing element.

Referring to FIG. 2, the optoelectronic device M further includes a first encapsulant 7 and a second encapsulant 8. The first encapsulant 7 is disposed on the substrate 1, and the second encapsulant 8 surrounds the first encapsulant 7. The first encapsulant 7 covers the carrier 2, the sensing element, and the light emitting element 4. Furthermore, as shown in FIG. 3, the first dam 5 and the second dam 6 jointly divide the first encapsulant 7 into a first part 71 and a second part 72 that are separated from and not in contact with each other. The first part 71 covers the light emitting element 4, and the second part 72 covers the carrier 2 and the sensing unit 3.

The second dam 6 and the second encapsulant 8 are integrally formed and made of a same material. Specifically, the second dam 6 is a part of the second encapsulant 8. In a process of producing the optoelectronic device M, the carrier 2 is disposed on the substrate 1, the sensing element is disposed on the carrier 2, and the light emitting element 4 is placed on the substrate 1. A first opaque adhesive material is disposed on and adjacent to a side of the carrier 2 by dispensing glue to form the first dam 5. The first dam 5 covers the side of the carrier 2, and a part of the first dam 5 extends to an upper surface 21 of the carrier plate 2. A transparent colloid, that is, the first encapsulant 7, is disposed on the substrate 1 to cover the carrier 2, the sensing element, the light emitting element 4, and the first dam 5. Outer peripheral parts of the first encapsulant 7 and parts of the first encapsulant 7 located above the first dam 5 are removed to form some accommodation spaces, and a second opaque adhesive material is molded to fill these spaces. Therefore, the second opaque adhesive material filled around the outside of the first encapsulant 7 forms a peripheral structure of the second encapsulant 8, and the second opaque adhesive material filled above the first dam 5 forms the second dam 6.

As mentioned above, both of the first dam 5 and the second dam 6 are combined to form as a light blocking structure, especially an opaque structure. Since the first dam 5 and the second dam 6 are made in different ways, the proportions of the constituent materials are different. The first dam 5 located at a bottom position needs to support the second dam 6 and therefore has high hardness. In addition, the first dam 5 is closer to the light emitting element 4 than the second dam 6, so as to have good light absorption and low light transmittance. Specifically, a Shore hardness of the first dam 5 is greater than or equal to D70, and a proportion of carbon black doped inside the first dam 5 is greater than 25%. A Shore hardness of the second dam 6 is D65, and a proportion of carbon black doped inside the second dam 6 is less than 25%. A light transmittance of the first dam 5 and the second dam 6 for a light with a wavelength between the 700 nm and 1500 nm is less than 0.2%, such that the noise interference (i.e., crosstalk) caused by stray light to the sensing element can be effectively reduced, and the light receiving performance can be improved. In addition, the hardness of the second dam 6 is preferably close to the hardness of the first encapsulant 7 to avoid peeling.

The first dam 5 includes a main body 51 and an extending portion 52 connected to a side of the main body 51, and the extending portion 52 is a part of the first dam 5 extending to the upper surface 21 of the carrier 2. The supporting function of the first dam 5 can be further enhanced and the noise interference can be reduced through structural design of the first dam 5 being adjacent to and covering the side of the carrier 2, and the first dam 5 including the extending portion 52. Due to the different ways of forming, a thixotropic index (Ti value for short) of the first dam 5 is relatively high. Preferably, the Ti value of the first dam 5 is greater than 5, and is optimally 10. A Ti value of the second dam 6 is relatively low, generally less than or equal to 2. The Ti value refers to the ability of a structure (such as the first dam 5 and the second dam 6) to restore its original shape after being damaged by a shear force. The higher the Ti value of a fluid, the stronger the ability of the fluid to restore its original shape.

Referring to FIG. 3, in a cross-sectional perspective of the optoelectronic device, the main body 51 and the extending portion 52 are tapered structures that taper from bottom to top. The first dam 5 is formed by using the first opaque adhesive material with a high hardness and a high Ti value (e.g., the best Ti value is 10), such that an aspect ratio of the first dam 5 is greater than 1. A position of the extending portion 52 extending to the upper surface 21 of the carrier 2 has a first width W1, a bottom of the main body 51 has a second width W2, and the first width W1 is less than or equal to ⅓ of the second width W2. Preferably, the first width W1 is greater than 50 μm. A width W3 of the second dam 6 is greater than a width (a sum of the first width W1 and the second width W2) of the first dam 5. Through the above structural design, the first dam 5 can be stably attached to one side of the carrier 2. In addition, a top (i.e., a position where the first dam 5 and the second dam 6 are in contact with each other) of the extending portion 52 and the upper surface 21 of the carrier 2 have a first height H1 therebetween. Preferably, the first height H1 is greater than 50 μm.

Referring to FIG. 3 and FIG. 4, in a cross-sectional perspective of the optoelectronic device M, a top of the first part 71 and a first central position 4C on an upper surface of the light emitting element 4 have a first vertical distance VL1 therebetween. A top of the second part 72 and a second central position 31 on an upper surface 31 of the sensing unit 3 have a second vertical distance VL2 therebetween. Moreover, the first central position 4C and a side 61 of the second dam 6 have a first horizontal distance HL1 therebetween, and the second central position 3C and another side 62 of the second dam 6 have a second horizontal distance HL2 therebetween. A ratio of the first horizontal distance HL1 to the first vertical distance VL1 is equal to a ratio of the second vertical distance VL2 to the second horizontal distance HL2. A ratio of the first width W1 of the extending portion 52 to the first height H1 is equal to a ratio of the first horizontal distance HL 1 to the first vertical distance VL1.

Through the distance proportional relationship shown in FIGS. 3 and 4, the relative positions of the barrier wall (i.e., the first dam 5 and the second dam 6), the sensing element, and the light emitting element 4 within the device can be obtained, so as to optimize the overall size of the device, further reduce noise interference, and improve the luminous efficiency. In other words, the optoelectronic device M provided by the present disclosure can improve the luminous efficiency and miniaturize the structure. Comparing the present disclosure with the existing technology, the optoelectronic device M provided by the present disclosure can increase the luminous efficiency by more than 20% and reduce the height of the device by more than 20%.

It should also be noted that existing photoelectric sensors are generally made by ways of planar packaging and has a large area. In comparison, in the optoelectronic device M of the present disclosure, the sensing unit 3 is stacked on the carrier 2 for re-routing through a redistribution layer (RDL) process, thereby reducing the area of the device and reducing routing complexity and improving product yield. The optoelectronic device M further forms a plurality of conductive vias T inside the carrier 2 by through-silicon via (TSV) processing to replace some of the wires, thereby reducing the number of wires and simplify the circuit design. In addition, since the sensing unit 3 is stacked on the carrier 2, the light receiving performance can be further improved.

Referring to FIG. 3, the substrate 1 has a top surface 101 and a bottom surface 102. The top surface 101 of the substrate 1 is a step structure jointly formed by a first upper surface P11 and a second upper surface P12, that is, the first upper surface P11 and the second upper surface P21 have a step difference therebetween. Furthermore, the first encapsulant 7 is disposed on the first upper surface P11 of the substrate 1 and the second encapsulant 8 is disposed on the second upper surface P12 of the substrate 1. Thereof, the second encapsulant 8 covers a portion of a side of the substrate 1 and surrounds the first encapsulant 7.

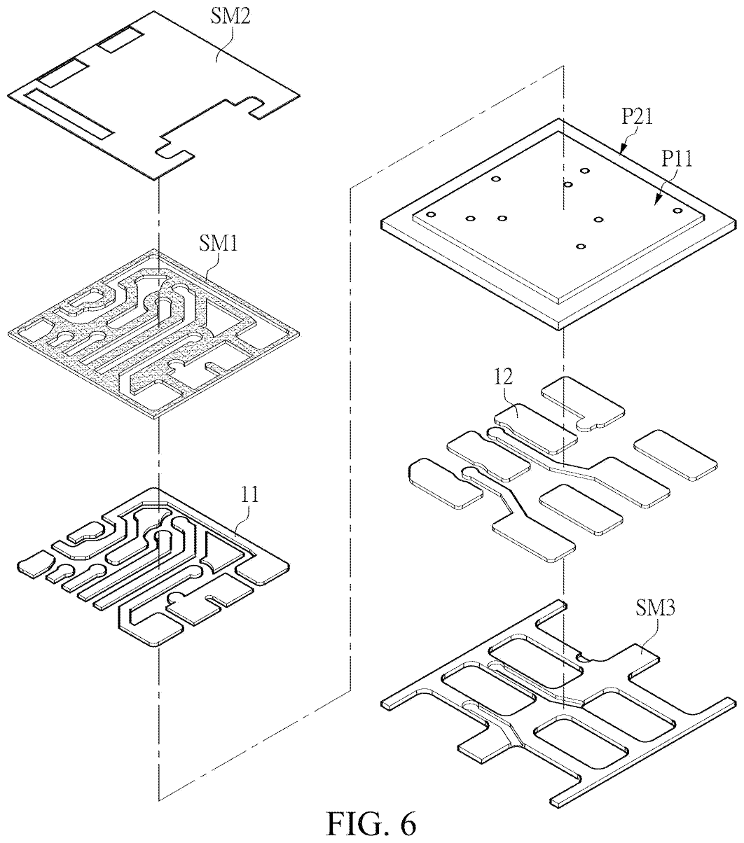

Referring to FIG. 3 and FIG. 6, the substrate 1 includes a plurality of first metal pads 11 and a plurality of second metal pads 12. The plurality of first metal pads 11 are disposed on the first upper surface P11, and the plurality of second metal pads 12 are disposed on the bottom surface 102 of the substrate 1. The plurality of first metal pads 11 are electrically connected to the plurality of second metal pads 12 through the plurality of conductive vias T. The substrate 1 further includes a first solder mask layer SM1 and a second solder mask layer SM2. The first solder mask layer SM1 is disposed on the first upper surface P11, and the first solder mask layer SM1 surrounds the plurality of first metal pads 11 and fills gaps between the plurality of first metal pads 11. A top of the first solder mask layer SM1 is flush with a top of each of first metal pads 11. The first encapsulant 7, the sensing element, the light emitting element 4, and the first dam 5 are disposed above a flat surface formed by the first solder mask layer SM1 and the first metal pads 11. The second solder mask layer SM2 is stacked on the flat surface formed by the first solder mask layer SM1 and the first metal pads 11, and the sensing element and the first dam 5 are disposed on the second solder mask layer SM2. Most of the flat surface is covered by the second solder mask layer SM2, and only a part of the first metal pads 11 is exposed to form a plurality of soldering regions SR. Therefore, the carrier 2 directly contacts the second solder mask layer SM2 while placed on the substrate 1. Through the design of the two-layer solder mask layers, the flatness of a bottom surface of the carrier 2 can be maintained to prevent the carrier 2 from tilting while being placed on the substrate 1, thereby increasing the stability of wiring and improving product reliability.

The sensing unit 3 and the carrier 2, and the carrier 2 and the plurality of soldering regions SR on the substrate 1 can be electrically connected through a plurality of metal wires E. It is worth mentioning that the bottom surface 102 of the substrate 1 is further provided with a third solder mask layer SM3 surrounding the plurality of first metal pads 11.

### Second Embodiment

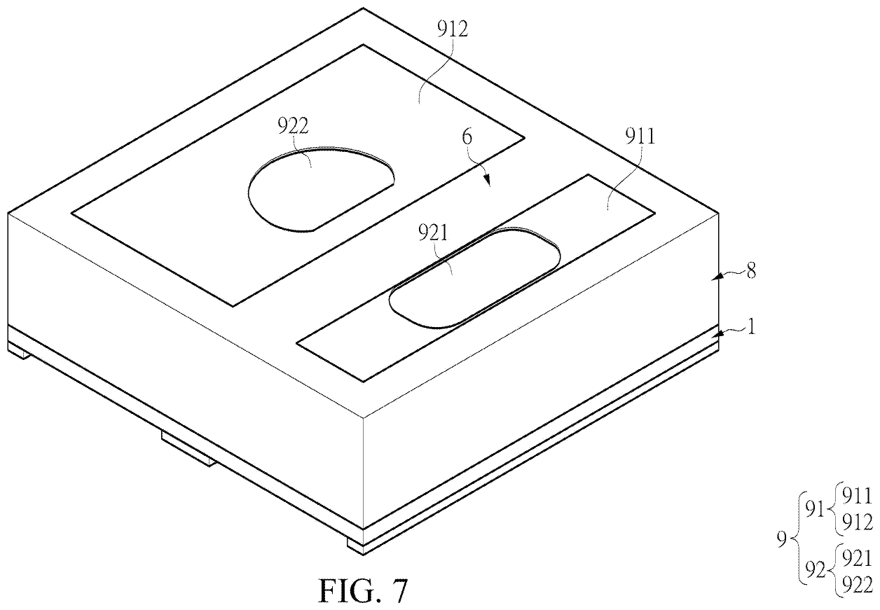

Referring to FIG. 7 to FIG. 9, an optoelectronic device M of the second embodiment has a structure similar to that of the first embodiment, and the similarities will not be reiterated herein. The main difference between the second embodiment and the first embodiment is as follows: in the second embodiment, the optoelectronic device M further includes a filtering structure 9. For example, the filtering structure 9 is disposed on a top surface 7S of the first encapsulant 7. The filtering structure 9 includes a light absorbing member 91 and a filter 92. Specifically, the light absorbing member 91 has an opening, and the filter 92 is disposed below the light absorbing member 91 and faces the opening 910. The light absorbing member 91 covers the top surface 7S of the first encapsulant 7. When the light absorbing member 91 and the filter 92 are stacked with each other, the opening 910 is covered by the filter 92, such that the filter 92 is exposed from the opening 910. When manufacturing the filtering structure 9, the filter 92 is formed on the top surface 7S of the first encapsulant 7 by sputtering, and the light absorbing member 91 covers the filter 92 to form the filtering structure 9.

Since the first encapsulant 7 is divided into the first part 71 and the second part 72 by the first dam 5 and the second dam 6, the filtering structure 9 include two parts accordingly, that is, the light absorbing member 91 includes a first light absorbing member 911 and a second light absorbing member 912, and the filter 92 includes a first filter 921 and a second filter 922. The first light absorbing member 911 and the first filter 921 are located on the top of the first part 71. The first light absorbing member 911 is stacked above the first filter 921. The first light absorbing member 921 is exposed from the opening 9110 of the first light absorbing member 911.

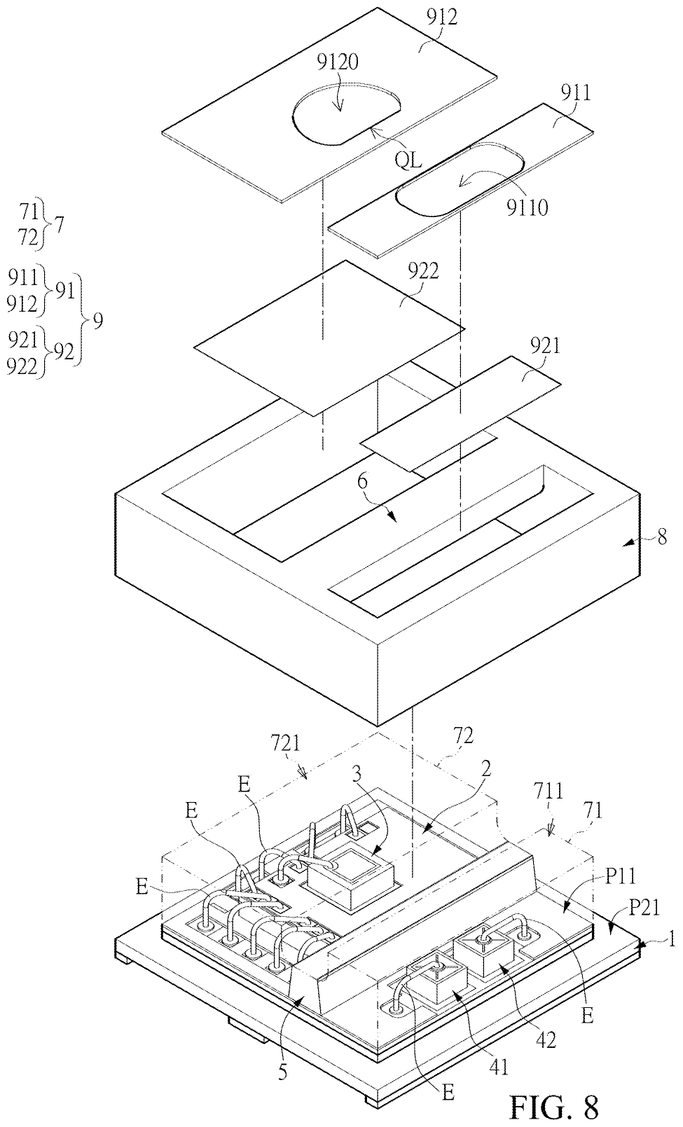

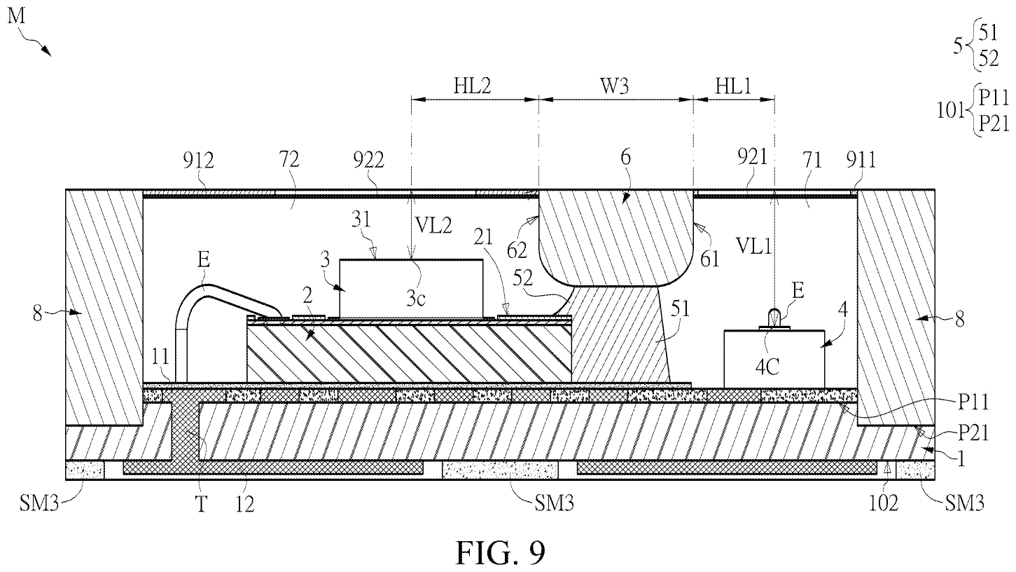

Referring to FIGS. 8 and 9, the opening 9110 of the first light absorbing member 911 for exposing the first filter 921 forms an elliptical shape, and an orthogonal projection of a center of the elliptical opening 9110 projected onto the light emitting element 4 overlaps a center of the light emitting element 4. Specifically, the orthogonal projection of the center of the elliptical opening 9110 projected onto the two light emitting units 41 and 42 overlap the centers of the two light emitting units 41 and 42. The opening 9120 of the second light absorbing member 912 for exposing the second filter 922 forms an arc shape or nearly a semicircular shape. A part of a semicircular outline of the opening 9120 is a straight line segment QL. An orthogonal projection of the straight line segment QL projected onto the sensing element preferably corresponds to one side of the sensing unit 3 or the light detection area adjacent to the barrier wall structure and the light emitting element 4. In other words, the orthogonal projection of the straight line segment QL projected onto the sensing unit 3 or the light detection area in the sensing element is adjacent to the barrier wall structure and the light emitting element 4. Through the structure of the first filter 921 and the second filter 922, the noise interference can be further reduced.

The filtering structure 9 (i.e., the light absorbing member 91 and the filter 92) can filter out unnecessary light, allowing the sensing element to receive light in a specific wavelength range, thereby reducing the noise interference. Furthermore, the filtering structure 9 is directly formed on the first encapsulant 7. In contrast with the present disclosure, the filter in the existing technology is arranged in an inner cavity of the housing. Therefore, the size of the filtering structure 9 of the present disclosure is not limited by the space inside the housing.

### Beneficial Effects of the Embodiments

In the optoelectronic device provided by the present disclosure, the first dam 5 and the second dam 6 jointly form a barrier wall structure. The first dam 5 covers a side of the sensing element, and the second dam 6 is disposed on the first dam 5. Therefore, the noise interference can be reduced, and the light receiving performance of the sensing element can be improved.

Moreover, in the optoelectronic device provided by the present disclosure, the first encapsulant 7 and the second encapsulant 8 jointly form a double-molding structure, and the sensing element can be a sensing unit 3 disposed on a carrier 2 (as shown in FIG. 3) or a carrier 2′ having a light detection area 20 on the surface thereof (as shown in FIG. 5). Therefore, the height of the overall structure can be reduced, so as to meet demands for miniaturization.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optoelectronic device, comprising:
a substrate;
a sensing element disposed on the substrate;
a light emitting element disposed on the substrate;
a first dam disposed on the substrate and covering a side of the sensing element; and
a second dam disposed on the first dam;
wherein the first dam and the second dam are located between the sensing element and the light emitting element.

2. The optoelectronic device according to claim 1, wherein the first dam includes a main body and an extending portion connected to the main body, and the extending portion extends to an upper surface of the sensing element.

3. The optoelectronic device according to claim 2, wherein the main body and the extending portion are tapered structures that taper from bottom to top.

4. The optoelectronic device according to claim 2, wherein a position of the extending portion extending to the upper surface of the sensing element has a first width, a bottom of the main body has a second width, and the first width is less than or equal to ⅓ of the second width.

5. The optoelectronic device according to claim 1, wherein an aspect ratio of the first dam is greater than 1.

6. The optoelectronic device according to claim 1, wherein a width of the second dam is greater than a width of the first dam.

7. The optoelectronic device according to claim 1, further comprising a first encapsulant disposed on the substrate and covering the sensing element and the light emitting element.

8. The optoelectronic device according to claim 7, further comprising a second encapsulant surrounding the first encapsulant.

9. The optoelectronic device according to claim 7, wherein the first encapsulant is divided into a first part and a second part separated from each other by the first dam and the second dam, the first part covers the light emitting element, and the second part covers the sensing element; wherein a top of the first part and a first central position on an upper surface of the light emitting element have a first vertical distance therebetween, the first central position and a side of the second dam have a first horizontal distance therebetween, a top of the second part and a second central position on an upper surface of the sensing element have a second vertical distance therebetween, the second central position and another side of the second dam have a second horizontal distance therebetween, and a ratio of the first horizontal distance to the first vertical distance is equal to a ratio of the second vertical distance to the second horizontal distance.

10. The optoelectronic device according to claim 9, wherein the first dam includes a main body and an extending portion connected to the main body, the extending portion extends to the upper surface of the sensing element, a position of the extending portion extending to the upper surface of the sensing element has a first width, a top of the extending portion and the upper surface of the sensing element have a first height therebetween, and a ratio of the first width to the first height is equal to a ratio of the first horizontal distance to the first vertical distance.

11. The optoelectronic device according to claim 7, further comprising a filtering structure disposed on a top surface of the first encapsulant, wherein the filtering structure includes a light absorbing member and a filter, the light absorbing member has an opening, and the filter is exposed from the opening.

12. The optoelectronic device according to claim 11, wherein the light absorbing member includes a first light absorbing member and a second light absorbing member, the filter includes a first filter and a second filter, the first filter is exposed from an opening of the first light absorbing member, an orthogonal projection of a center of the opening projected onto the light emitting element overlaps a center of the light emitting element; wherein the second filter is exposed from an arc-shaped opening of the second light absorbing member, a part of a contour of the arc-shaped opening is a straight line segment, and an orthogonal projection of the straight line segment projected onto the substrate overlaps the sensing element and is adjacent to the first dam and the second dam.

13. The optoelectronic device according to claim 1, wherein a Shore hardness of the first dam is greater than or equal to D70 and higher than a Shore hardness of the second dam.

14. The optoelectronic device according to claim 1, wherein a proportion of carbon black doped inside the first dam is greater than 25% and a proportion of carbon black doped inside the second dam is less than 25%.

15. An optoelectronic device, comprising:
a substrate;
a light receiver disposed on the substrate;
a light emitter disposed on the substrate and spaced apart from the light emitter;
and a light blocking structure disposed between the light receiver and the light emitter and covering a side and partially a top of the light receiver.

16. The optoelectronic device according to claim 15, wherein light blocking structure comprises a first dam that tapers from bottom to top.

17. The optoelectronic device according to claim 15, wherein the light blocking structure comprises a first dam disposed on the carrier and a second dam disposed on the top of the first dam.

18. The optoelectronic device according to claim 17, wherein a width of the second dam is greater than a width of the first dam.

19. The optoelectronic device according to claim 15, further comprising a first encapsulant disposed on the carrier and covering the light emitter and the light receiver.

20. The optoelectronic device according to claim 19, further comprising a second encapsulant surrounding the first encapsulant, wherein the substrate has a top surface, the top surface includes a first upper surface and a second upper surface, the first upper surface and the second upper surface have a step difference therebetween, and the first encapsulant is disposed on the first upper surface and the second encapsulant is disposed on the second upper surface.
